(19) United States
(12) Patent Application Publication
(10) Pub. No.: US 2006/0226438 A1
(43) Pub. Date: Oct. 12, 2006

(54) Solid-state imaging device

(75) Inventors: Motonari Katsuno, Kyoto-shi (JP); Yoshiyuki Matsunaga, Kyoto-shi (JP)

Correspondence Address: HAMRE, SCHUMANN, MUELLER & LARSON P.C., P.O. BOX 2902-0902, MINNEAPOLIS, MN, 55402, US

(73) Assignee: Matsushita Electric Industrial Co., Ltd., Kadoma-shi (JP)

(21) Appl. No.: 11/386,324

(22) Filed: Mar. 22, 2006

(30) Foreign Application Priority Data
Apr. 11, 2005 (JP) 2005-113696

(51) Int. Cl. H01L 31/111; H01L 31/06

(52) U.S. Cl. 257/113; 257/461; 257/E27.133

(57) ABSTRACT

A solid-state imaging device including an n-type semiconductor substrate including a photoelectric conversion portion, and a signal detection portion for detecting a signal charge is used. The photoelectric conversion portion is provided with a photodiode, and a p-well that overlaps the photoelectric conversion portion and the signal detection portion when viewed in a thickness direction of the semiconductor substrate is formed in the semiconductor substrate. The p-well is formed so that a surface side interface is located below a surface side interface of the photodiode. Preferably, the surface side interface of the p-well is located below a lower side interface of the photodiode and an impurity profile of the p-well does not overlap that of the photodiode. At this time, a non-dope region is present between the photodiode and the p-well.

### BACKGROUND OF THE INVENTION

1. Field of the Invention

The present invention relates to a solid-state imaging device.

2. Description of Related Art

Conventionally, MOS imaging devices and CCD (charge coupled device) imaging devices are known as prominent solid-state imaging devices. Among them, in a MOS imaging device, incident light is converted into a signal charge by a photoelectric conversion region (a photodiode), and the signal charge is amplified by a transistor. More specifically, the potential of the photoelectric conversion region is modulated by the signal charge generated from the photoelectric conversion. Then, the amplification coefficient of the amplifying transistor varies according to that potential.

Also, in the case of the MOS imaging device, the transistor for amplifying the signal charge is included in a pixel portion. Accordingly, the MOS imaging device easily can be adapted to a decrease in pixel size and an increase in the number of pixels and thus holds great promise in this respect. Further, the MOS imaging device also has features of high sensitivity and low power consumption as well as a feature of capability of operation by a single power source.

Moreover, the MOS imaging device also has an advantage over the CCD imaging device in that various circuits can be incorporated easily onto a silicon substrate provided with pixels. In the MOS imaging device, it is possible to incorporate peripheral circuits (a register circuit and a timing circuit), an A/D conversion circuit (an analog-digital conversion circuit), an instruction circuit, a D/A conversion circuit (a digital-analog conversion circuit), a DSP (a digital signal processor) etc., for example. Since functional circuits can be incorporated onto the silicon substrate on which pixels are formed in the MOS imaging device as described above, it is possible to lower the cost compared with the CCD imaging device.

The MOS imaging device has a commonality with the CCD imaging device in that the photoelectric conversion is carried out in the photodiode formed near the surface of the silicon substrate. Furthermore, in both imaging devices, a plurality of the photodiodes are formed and arranged in an array. However, in the CCD imaging device, the signal charge obtained by the photoelectric conversion is transferred in a diffusion region (a signal transfer region) provided differently from the pixels. Therefore, in the CCD imaging device, electrons generated by the photoelectric conversion may leak, causing a problem of deteriorating image quality.

More specifically, the CCD imaging device has a problem of easily developing phenomena such as smear, blooming and color mixture. The smear is a phenomenon in which, when intense light enters each pixel, electrons generated in the photodiode leak into the signal transfer region, causing vertical lines in an image. Also, the blooming is a phenomenon in which, when intense light enters each pixel as in the case of smear, electrons leak into adjacent pixels, causing the region that the intense light has entered to form a blurred image. The color mixture is a phenomenon in which electrons are generated in the pixel that light has entered deeply into the substrate and leak into adjacent pixels, so that colors appear to be mixed in an image.

On the other hand, in the MOS imaging device, the signal charge is transferred through wirings connected to the photodiode (see JP 2000-150848 A, for example). This will be described referring to FIG. 12. FIG. 12 schematically shows a circuit configuration of a conventional MOS imaging device.

As shown in FIG. 12, the MOS imaging device includes a plurality of pixels 111 arranged in an array in an image capturing region 110 on a silicon substrate. Each of the pixels 111 includes a photodiode 112 serving as a photoelectric conversion element, a charge transfer transistor 113, a reset transistor 114 for erasing an electric charge and an amplifying transistor 115.

In each of the pixels, the photodiode 112 and the charge transfer transistor 113 function as a photoelectric conversion portion for converting incident light into a signal charge. Also, the reset transistor 114 and the amplifying transistor 115 function as a signal detection portion for detecting a signal charge.

In the periphery of the image capturing region 110 on the silicon substrate, a vertical shift register 121 for vertical scanning and a horizontal shift register 122 for horizontal scanning are formed. For each horizontal line, the charge transfer transistor 113 in each of the pixels 111 is connected to the vertical shift register 121 by a horizontal pixel selection wiring 124. Also, for each horizontal line, the reset transistor 114 is connected to the vertical shift register 121 by a reset wiring 123. For each vertical line, the amplifying transistor 115 in each of the pixels 111 is connected to the horizontal shift register 122 by a vertical signal wiring 126. Numeral 125 denotes a current stabilizing transistor, and numeral 128 denotes a voltage input transistor.

The following is a description of the operations of the vertical shift register 121 and the horizontal shift register 122. First, the vertical shift register 121 selects a horizontal line designated by a control circuit (not shown). More specifically, the vertical shift register 121 achieves a state in which the charge transfer transistor 113 on the designated horizontal line is ON and the rest of the charge transfer transistors 113 are OFF.

Next, the horizontal shift register 122 applies a pulse to the individual vertical signal wirings 126 sequentially from left to right so as to turn ON the individual amplifying transistors 115 on the selected horizontal line sequentially, thereby reading out signal charges stored in the pixels 111. In this manner, the signal charges are read out for all of the horizontal lines, thus outputting the signal charges of all of the pixels.

As described above, unlike the CCD imaging device, the signal charge is transferred through the wirings in the MOS imaging device, so that there is no room for smear occurrence. Also, in the MOS imaging device, the circuit for detecting a signal charge is arranged at the midpoint between adjacent photodiodes. Consequently, compared with the CCD imaging device, the MOS imaging device can suppress the signal charge leakage between adjacent pixels, thus suppressing the occurrence of blooming and color mixture.

However, the MOS imaging device cannot suppress blooming and color mixture completely. Further, in recent years, with the advent of digital still cameras and camera-equipped mobile phones, there has been an increasing demand for the MOS imaging devices, which can be produced at a lower cost than the CCD imaging device. Accordingly, a higher image quality for the MOS imaging device is being requested. In order to respond to such a request, for example, JP 2000-150848 A mentioned above discloses a MOS imaging device that deals with blooming and color mixture.

Here, the configuration of the MOS imaging device illustrated in JP 2000-150848 A will be described. FIG. 13 is a sectional view showing a structure of a conventional MOS imaging device dealing with blooming and color mixture. It should be noted that FIG. 13 shows a part of the pixels. In FIG. 13, members assigned the same reference signs as those in FIG. 12 show specific configurations of the members shown in FIG. 12.

In the MOS imaging device shown in FIG. 13, a p-well 131 is formed on the surface of a silicon substrate 130. Also, in the region where the p-well 131 is formed, the photodiodes 112, the charge transfer transistors 113, the reset transistors 114 and the amplifying transistors 115 are formed. Further, the silicon substrate 130 has an n-type electrical conductivity. Accordingly, in the MOS imaging device shown in FIG. 13, when electrons are generated in an area deeper than the p-well 131, they are emitted to an area still deeper than that area by the p-well 131. Therefore, according to the MOS imaging device shown in FIG. 13, the occurrence of blooming and color mixture can be suppressed further.

In an example illustrated by FIG. 13, the p-well 131 is formed by ion implantation of p-type impurities into the silicon substrate 130 or epitaxial growth. The impurity concentration of the p-well 131 is set to 1×10¹⁴ ions/cm³ to 1×10¹⁶ ions/cm³. Although not shown in the figure, a p-well also is formed in a peripheral region of the image capturing region 110 (see FIG. 12). The impurity concentration of the p-well in the peripheral region is set to 1×10¹⁶ ions/cm³ to 1×10¹⁸ ions/cm³.

In FIG. 13, numeral 138 denotes an element isolation region. Numeral 117 denotes a semiconductor region used as a source or a drain of various transistors. The photodiode 112 also is used as a source of the charge transfer transistor 113. Numeral 134 denotes a gate electrode of the charge transfer transistor 113, numeral 135 denotes a gate electrode of the reset transistor 114, and numeral 136 denotes a gate electrode of the amplifying transistor 115. Numeral 132 denotes a photoelectric conversion portion, and numeral 133 denotes a signal detection portion.

Further, numerals 118, 119 and 129 denote contact plugs, and numeral 120 denotes a wiring for connecting the contact plugs 118 and 119. Numeral 137 denotes a drain voltage input wiring and is connected to a drain region (the semiconductor region 117) of the amplifying transistor 115 by the contact plug 129. Numerals 141, 142 and 143 denote interlayer insulating films. Numeral 139 denotes a light-shielding film with openings provided in a matrix, numeral 140 denotes a focusing lens for focusing external light on the photodiode 112.

However, in the MOS imaging device shown in FIG. 13, the p-well 131 emits even electrons stored in the photodiodes 112 to a surface opposite to the circuit formation surface of the silicon substrate 130 (a back surface). Therefore, there is a problem that the MOS imaging device shown in FIG. 13 has a smaller maximum number of electrons that can be stored in the photodiode 112 (the saturation number of electrons) and a lower sensitivity than the MOS imaging device provided with no p-well 131.

Further, in recent years, with the reduction of pixel size accompanying an increase in the number of pixels, the size of the photodiode 112 tends to become smaller, making it difficult to maintain the maximum number of electrons.

On the other hand, in order to achieve a higher image quality in the MOS imaging device, it is necessary to reduce the influence of noise. Therefore, the maximum number of electrons that can be stored in the photodiode 112 has to be increased as much as possible.

### SUMMARY OF THE INVENTION

It is an object of the present invention to solve the problems described above and to provide a solid-state imaging device capable of suppressing both the occurrence of blooming and color mixture and the reduction of the maximum number of electrons in the photodiode and the sensitivity.

In order to achieve the above-mentioned object, a solid-state imaging device according to the present invention includes an n-type semiconductor substrate including a photoelectric conversion portion for converting incident light into a signal charge, and a signal detection portion for detecting the signal charge. The photoelectric conversion portion includes a photodiode formed in the semiconductor substrate, the semiconductor substrate includes a p-well that overlaps the photoelectric conversion portion and the signal detection portion when viewed in a thickness direction of the semiconductor substrate, and the p-well is formed so that a surface side interface is located below a surface side interface of the photodiode.

Due to the above, in the solid-state imaging device according to the present invention, the surface side interface of the p-well is located in an area deeper than in the conventional device. Thus, the solid-state imaging device according to the present invention suppresses the emission of electrons stored in the photodiode to the back surface of the semiconductor substrate and emits electrons generated in the area deeper than the p-well to the back surface of the semiconductor substrate. As a result, the present invention can suppress both the occurrence of blooming and color mixture and the reduction of the maximum number of electrons in the photodiode and the sensitivity. This further suppresses the deterioration of image quality caused by the reduction of pixel size even when the number of pixels increases in the solid-state imaging device of the present invention, so that a high quality image can be maintained.

### BRIEF DESCRIPTION OF THE DRAWINGS

FIG. 1 is a sectional view showing a structure of a solid-state imaging device according to Embodiment 1 of the present invention.

FIG. 2 shows impurity profiles of photodiodes, with FIG. 2A showing the impurity profiles in a conventional solid-state imaging device shown in FIGS. 12 and 13, FIG. 2B showing the impurity profiles in the solid-state imaging device according to Embodiment 1 shown in FIG. 1 and FIG. 2C showing the impurity profiles in another example of Embodiment 1.

FIGS. 3A to 3D are sectional views showing a series of major steps in a method for manufacturing the solid-state imaging device shown in FIG. 1.

FIG. 4 is a sectional view showing a structure of a solid-state imaging device according to Embodiment 2 of the present invention.

FIGS. 5A to 5D are sectional views showing a series of major steps in a method for manufacturing the solid-state imaging device shown in FIG. 4.

FIG. 6 is a sectional view showing a structure of a solid-state imaging device according to Embodiment 3 of the present invention.

FIG. 7 is a sectional view showing a structure of a solid-state imaging device according to Embodiment 4 of the present invention.

FIGS. 8A to 8D are sectional views showing a series of major steps in a method for manufacturing the solid-state imaging device shown in FIG. 7.

FIG. 9 is a sectional view showing a structure of a solid-state imaging device according to Embodiment 5 of the present invention.

FIG. 10 is a sectional view showing a structure of a solid-state imaging device according to Embodiment 6 of the present invention.

FIGS. 11A to 11D are sectional views showing a series of major steps in a method for manufacturing the solid-state imaging device shown in FIG. 10.

FIG. 12 schematically shows a circuit configuration of a conventional MOS imaging device.

FIG. 13 is a sectional view showing a structure of the conventional MOS imaging device dealing with blooming and color mixture.

### DETAILED DESCRIPTION OF THE INVENTION

A solid-state imaging device according to the present invention includes an n-type semiconductor substrate including a photoelectric conversion portion for converting incident light into a signal charge, and a signal detection portion for detecting the signal charge. The photoelectric conversion portion includes a photodiode formed in the semiconductor substrate, the semiconductor substrate includes a p-well that overlaps the photoelectric conversion portion and the signal detection portion in a thickness direction of the semiconductor substrate, and the p-well is formed so that a surface side interface is located below a surface side interface of the photodiode.

In the above-described solid-state imaging device according to the present invention, the p-well can be formed so that the surface side interface of the p-well is located below a lower side interface of the photodiode and an impurity profile of the p-well does not overlap that of the photodiode, and a region in which no impurity is introduced by a step other than a forming step of the semiconductor substrate can be present between the photodiode and the p-well.

In this case, it is possible further to suppress the occurrence of blooming and color mixture and suppress the reduction of the maximum number of electrons in the photodiode and the sensitivity. Also, it is preferable that an impurity concentration of n-type impurities is 1×10¹² ions/cm³ to 1×1016 ions/cm³ and that of p-type impurities is 1×10¹² ions/cm³ to 1×10¹⁶ ions/cm³ in the region in which no impurity is introduced by the step other than the forming step of the semiconductor substrate.

Also, in the above-described solid-state imaging device according to the present invention, the p-well may be formed so that the surface side interface of the p-well is located between a surface side interface of the photodiode and a lower side interface thereof.

In the above-described solid-state imaging device according to the present invention, the semiconductor substrate can include a second p-well that is located above the p-well and has a higher impurity concentration than the p-well, and the signal detection portion can be formed in a region where the second p-well is formed. This makes it possible to improve the performance of a transistor element forming the signal detection portion, thus suppressing phenomena such as latch up.

Also, in the above-described solid-state imaging device according to the present invention, a p-type buried region having a higher impurity concentration than the p-well can be provided below the p-well. This further suppresses the intrusion of electrons generated in an area deeper than the p-well into the photoelectric conversion portion.

In the above-described solid-state imaging device according to the present invention, a plurality of the photoelectric conversion portions and a plurality of the signal detection portions can be formed in the semiconductor substrate. The plurality of the photoelectric conversion portions and the plurality of the signal detection portions can function as a plurality of pixels. The plurality of pixels can be arranged in a matrix, and an element isolation region can be formed between the pixels adjacent to each other in the semiconductor substrate. In this case, it is preferable that the semiconductor substrate includes a p-type second buried region that is formed below the element isolation region so as to have a higher impurity concentration than the p-well and separate the pixels. Also, this further suppresses the intrusion of electrons generated in an area deeper than the p-well into the photoelectric conversion portion.

Further, in the above-described solid-state imaging device according to the present invention, the semiconductor substrate may include a second p-well that is located above the p-well and has a higher impurity concentration than the p-well, and a p-type semiconductor region having a higher impurity concentration than the second p-well in a region including an interface between the element isolation region and other regions. The signal detection portion may be formed in a region where the second p-well is formed. Also, this further suppresses the intrusion of electrons generated in an area deeper than the p-well into the photoelectric conversion portion.

### Embodiment 1

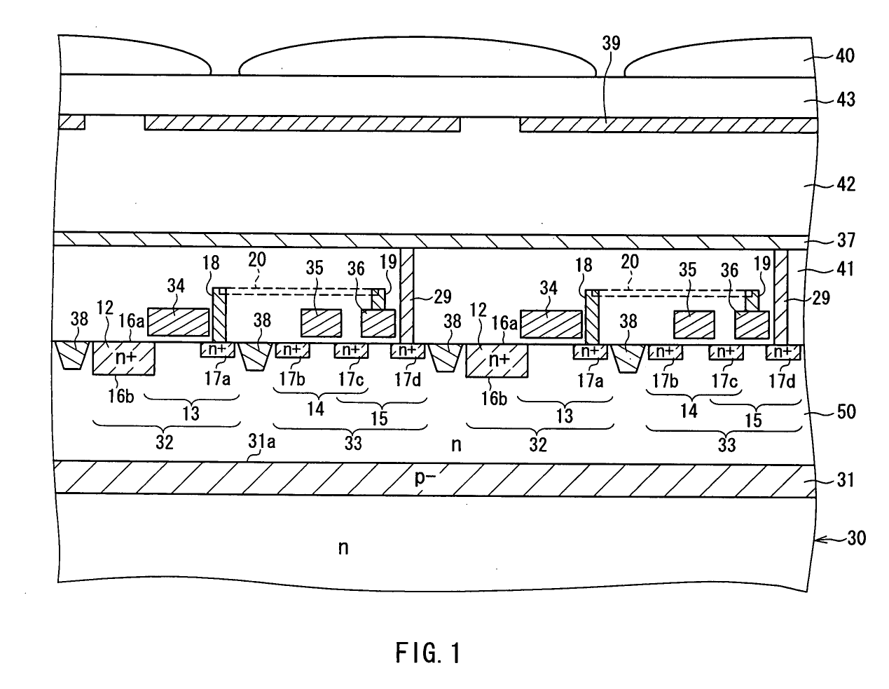

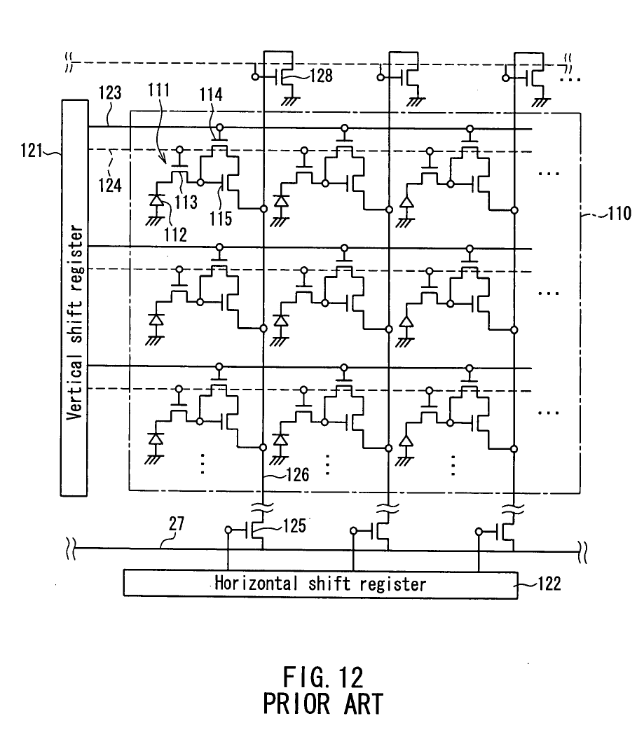

The following is a description of a solid-state imaging device according to Embodiment 1 of the present invention, with reference to FIGS. 1 to 3. The solid-state imaging device according to Embodiment 1 is a MOS imaging device and has a circuit configuration similar to the conventional MOS imaging device shown in FIG. 12 except for its cross-sectional structure. This will be described in the following.

The cross-sectional structure of the solid-state imaging device according to Embodiment 1 will be described referring to FIG. 1. FIG. 1 is a sectional view showing the structure of the solid-state imaging device according to Embodiment 1 of the present invention. As shown in FIG. 1, a p-well 31 is formed in a semiconductor substrate 30 so as to overlap photoelectric conversion portions 32 and signal detection portions 33 when viewed in a thickness direction of the semiconductor substrate 30. In other words, the p-well 31 is formed so that its formation region overlaps a formation region of the photoelectric conversion portions 32 and the signal detection portions 33 when the semiconductor substrate 30 is observed from its thickness direction.

Also, in Embodiment 1, the p-well 31 is formed so that its surface side interface 31a is located below lower side interfaces 16b of photodiodes 12. Furthermore, between the photodiodes 12 and the p-well 31, a region 50 in which no impurity is introduced by a step other than the step of forming the semiconductor substrate 30, for example, an ion implantation step (in the following, referred to as a “non-dope region”) is provided.

In Embodiment 1, an n-type silicon substrate is used as the semiconductor substrate 30. Therefore, although there is no impurity by the ion implantation, n-type impurities (n-type ions) introduced at the time of epitaxial growth when manufacturing the semiconductor substrate 30 are present. More specifically, it is preferable that an impurity region in the non-dope region 50 has an impurity concentration of the n-type impurities of 1×10¹² ions/cm³ to 1×10¹⁶ ions/cm³, in particular, 1×10¹³ ions/cm³ to 1×10¹⁵ ions/cm³ and an impurity concentration of the p-type impurities of 1×10¹² ions/cm³ to 1×10¹⁶ ions/cm³, in particular, 1 x 1013 ions/cm³ to 1×10¹⁵ ions/cm³.

As shown in FIG. 1, also in Embodiment 1, the photodiodes 12 are formed by an n-type semiconductor region and stores signal charges according to an intensity of incident light, similarly to the conventional example. It also is possible to form a p-type surface inversion layer on a surface of the photodiode 12. Also, the photodiode 12 and a charge transfer transistor 13 form the photoelectric conversion portion 32 for converting incident light into a signal charge. A reset transistor 14 and an amplifying transistor 15 form the signal detection portion 33 for detecting a signal charge. An element isolation region 38 is formed between the photoelectric conversion portion 32 and the signal detection portion 33.

Moreover, the charge transfer transistor 13 uses the photodiode 12 as a source and further includes an n-type semiconductor region 17a used as a drain and a gate electrode 34. The reset transistor 14 includes an n-type semiconductor region 17b used as a source, a gate electrode 35 and an n-type semiconductor region 17c used as a drain.

The semiconductor region 17c also is used as a source of the amplifying transistor 15. The amplifying transistor 15 includes a gate electrode 36 and an n-type semiconductor region 17d used as a drain. The drain of the charge transfer transistor 13 (the semiconductor region 17a) and the gate electrode 36 of the amplifying transistor 15 are connected via a contact plug 18, a wiring 20 and a contact plug 19.

Similarly to the conventional example, interlayer insulating films 41 to 43, a drain voltage input wiring 37, a light-shielding film 39 with openings provided in a matrix and a focusing lens 40 for focusing external light to the photodiode 12 are formed on a substrate surface of the semiconductor substrate 30. The semiconductor region 17d used as a drain of the amplifying transistor 15 is connected to the drain voltage input wiring 37 by a contact plug 29.

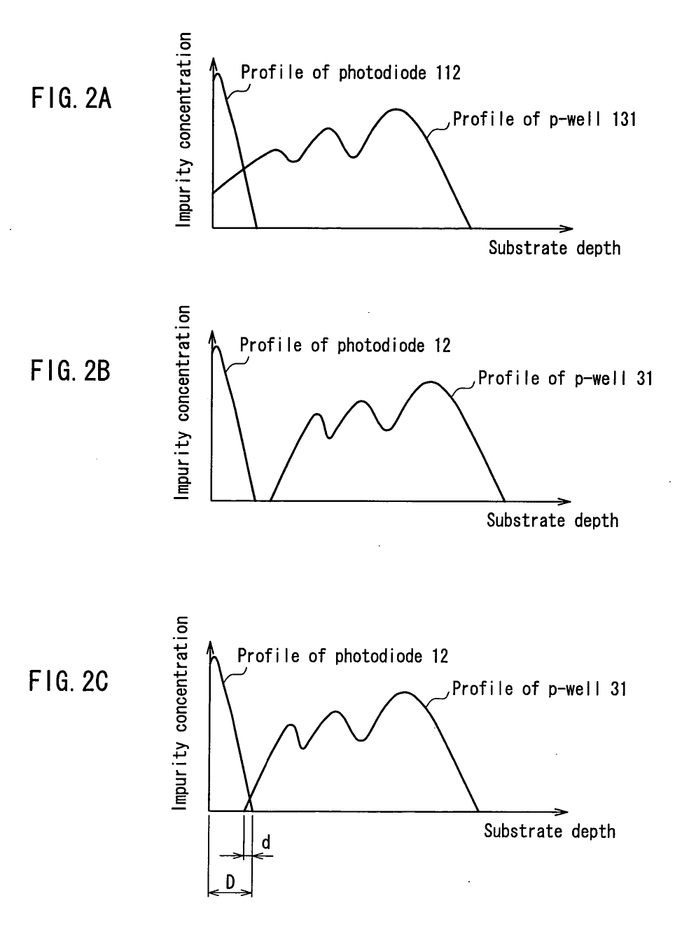

Here, referring to FIG. 2, the impurity profile of the photodiode 12 will be described in contrast with the conventional example. FIG. 2 shows the impurity profiles of photodiodes, with FIG. 2A showing the impurity profiles in the conventional solid-state imaging device shown in FIGS. 12 and 13, FIG. 2B showing the impurity profiles in the solid-state imaging device according to Embodiment 1 shown in FIG. 1 and FIG. 2C showing the impurity profiles in another example of Embodiment 1.

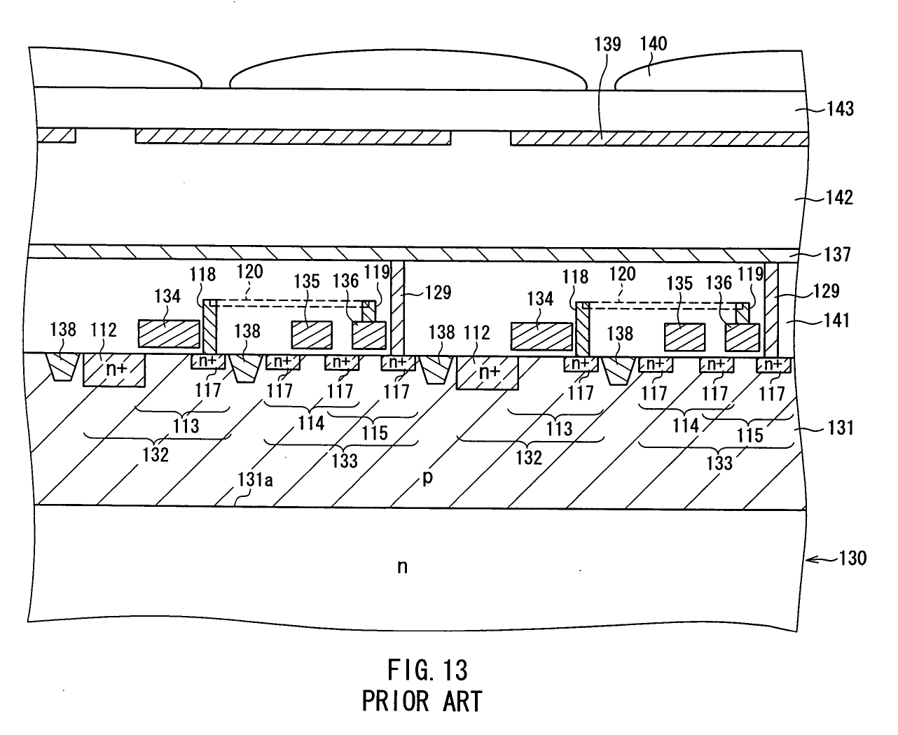

As shown in FIG. 13, in the conventional MOS imaging device, a surface side interface of the photodiode 112 and a surface side interface of the p-well 131 both coincide with the substrate surface. Therefore, as shown in FIG. 2A, the impurity profile of the photodiode 112 overlaps that of the p-well 131 entirely over the depth direction of the substrate.

In contrast, as shown in FIG. 2B, in Embodiment 1, the p-well 31 is formed so that its impurity profile does not overlap that of the photodiode 12. Accordingly, in Embodiment 1, the non-dope region 50 is present between the photodiode 12 and the p-well 31 as shown in FIG. 1.

As described above, in Embodiment 1, the photodiodes 12 are formed above the surface side interface 31a of the p-well 31. This makes it possible to suppress an excessive emission of electrons stored in the photodiodes 12 to the back surface of the semiconductor substrate 30. Thus, according to Embodiment 1, the reduction of the maximum number of electrons of the signal charge in the photodiodes 12 and the sensitivity can be suppressed.

Moreover, since the p-well 31 overlaps the photodiodes 12 when viewed in the thickness direction of the semiconductor substrate 30, electrons generated in an area deeper than the p-well 31 are emitted to the back surface of the semiconductor substrate 30 without intruding into adjacent pixels (the photoelectric conversion portions 32). Consequently, in accordance with Embodiment 1, it is possible to suppress the occurrence of blooming and color mixture.

Also, in Embodiment 1, the p-well 31 is not limited to that shown in FIGS. 1 and 2B. The p-well 31 is appropriate as long as it is formed so that its surface side interface 31a is located below surface side interfaces 16a of the photodiodes 12. For example, as shown in FIG. 2C, the surface side interface of the p-well 31 may be located between the surface side interface of the photodiode (the substrate surface) and the lower side interface thereof, and their impurity profiles may overlap each other partially.

In this case, it also is possible to suppress the excessive emission of the electrons stored in the photodiode 12 to the back surface of the semiconductor substrate 30, thereby obtaining the effects described above. Further, in the case of FIG. 2C, it is preferable that a portion of the impurity profile of the p-well 31 overlapping that of the photodiode 12 is set to have a length d in a depth direction of not greater than D/2, where D indicates the length of the impurity profile of the photodiode 12 in the depth direction.

As shown in FIGS. 2B and 2C, it is preferable that the impurity profile of the p-well 31 is given a slope in which an impurity concentration rises toward the back surface of the semiconductor substrate 30. In that case, the electrons emitted from the photodiode 12 can be returned to the photodiode 12. Also, it is possible to facilitate the emission of the electrons generated in the area deeper than the p-well 31 to the back surface of the semiconductor substrate 30.

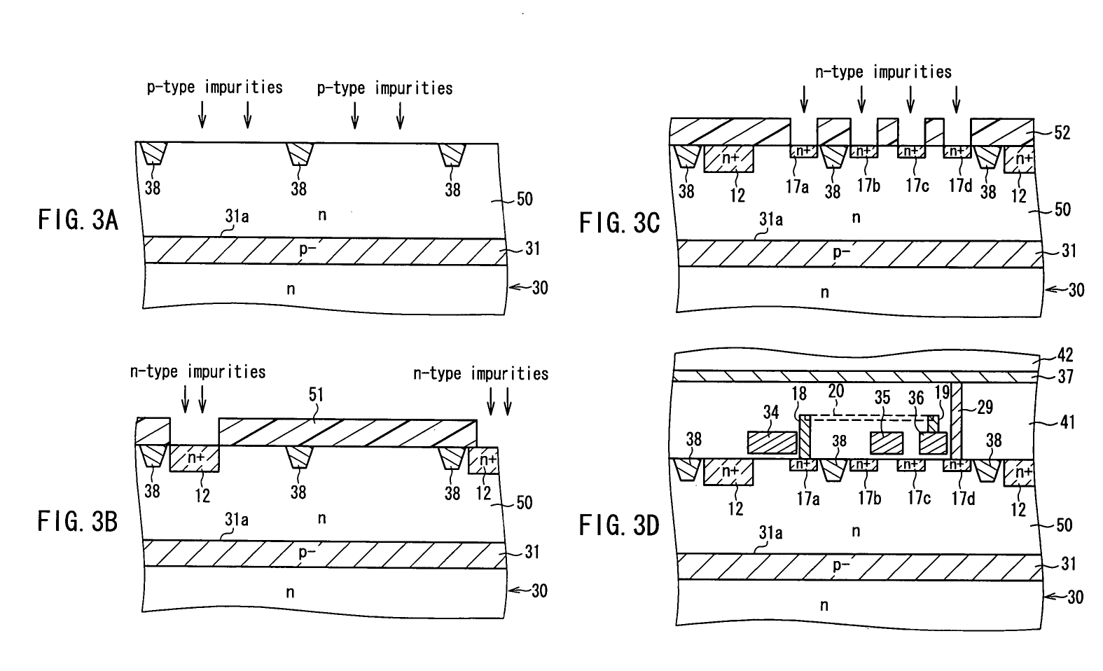

Now, the method for manufacturing the solid-state imaging device according to Embodiment 1 shown in FIG. 1 will be described referring to FIG. 3. FIGS. 3A to 3D are sectional views showing a series of major steps in the method for manufacturing the solid-state imaging device shown in FIG. 1.

First, as shown in FIG. 3A, a plurality of the element isolation regions 38 are formed at predetermined intervals in the semiconductor substrate 30. In Embodiment 1, the element isolation regions 38 having a buried trench structure are formed by an STI (Shallow Trench Isolation) process. Further, in Embodiment 1, it is preferable that the semiconductor substrate 30 is set to have a resistivity of at least 10Ω, in particular, 10Ω to 50Ω. This is because, when the resistivity of the semiconductor substrate 30 becomes smaller than 10Ω, the variation in potential caused by the ion implantation into the semiconductor substrate becomes smaller, making an inversion to a p-type region particularly difficult.

Next, ions of p-type impurities such as boron (B) are implanted so as to form the p-well 31 having the impurity profile shown in FIG. 2B inside the semiconductor substrate 30. At this time, the p-well 31 preferably is formed so that the surface side interface 31a of the p-well 31 is located below the substrate surface of the semiconductor substrate 30, preferably, at a distance of 1 to 20 μm from the substrate surface and the impurity concentration is 1×10¹² ions/cm³ to 1×10¹⁷ ions/cm³, particularly preferably, 1×10¹⁴ ions/cm³ to 1×10¹⁶ ions/cm³.

Also, the ion implantation is carried out under the condition set such that the non-dope region 50 is present between the photodiodes 12 and the p-well 31 even when the impurities in the p-well 31 are diffused due to a heat treatment after the ion implantation. Furthermore, it is preferable that the p-well 31 is distributed over a wide range in such a manner as to have a gentle concentration gradient. More specifically, it is preferable that the p-well 31 is formed by 2 to 10 times of ion implantation with an acceleration energy of 100 keV to 2000 keV and a dose of 1×10¹⁴ ions/cm² to 1×10¹⁶ ions/cm².

Subsequently, as shown in FIG. 3B, the photodiodes 12 are formed above the p-well 31 (near the surface of the semiconductor substrate 30). More specifically, a resist pattern 51 having openings in a formation region of the photodiodes 12 first is formed on the substrate surface of the semiconductor substrate 30. Next, using the resist pattern 51 as a mask, ions of n-type impurities such as arsenic (As) are implanted. At this time, the ion implantation preferably is carried out under the condition set so that, for example, the acceleration energy (acceleration voltage) is 100 keV to 1000 keV and the dose is 1×10¹² ions/cm² to 5×10¹² ions/cm². Thereafter, the resist pattern 51 is removed.

Then, as shown in FIG. 3C, the semiconductor regions 17a to 17d serving as the source or the drain of the transistors are formed above the p-well 31 (near the surface of the semiconductor substrate 30). More specifically, a resist pattern 52 having openings in a formation region of the semiconductor regions 17a to 17d first is formed on the substrate surface of the semiconductor substrate 30. Next, using the resist pattern 52 as a mask, ions of n-type impurities such as arsenic (As) are implanted. At this time, the ion implantation preferably is carried out under the condition set so that, for example, the acceleration energy (acceleration voltage) is 10 keV to 100 keV and the dose is 1×10¹² ions/cm² to 1×10¹⁶ ions/cm². Thereafter, the resist pattern 52 is removed.

Subsequently, as shown in FIG. 3D; the gate electrodes 34 to 36, the contact plugs 18, 19 and 29, the wiring 20, the interlayer insulating films 41 to 43, the drain voltage input wiring 37, the light-shielding film 39 and the focusing lens 40 are formed, thus obtaining the solid-state imaging device shown in FIG. 1. In FIG. 3D, the interlayer insulating film 43, the light-shielding film 39 and the focusing lens 40 are omitted.

Incidentally, the gate electrodes 34 to 36 may be formed prior to the step illustrated by FIG. 3C. In this case, it is possible to use the gate electrodes 34 to 36 as a mask, so that the semiconductor regions 17a to 17d serving as the source or the drain can be formed in a self-aligned manner. Also, in this case, since the resist pattern 52 does not have to be formed, it is possible to reduce the steps.

### Embodiment 2

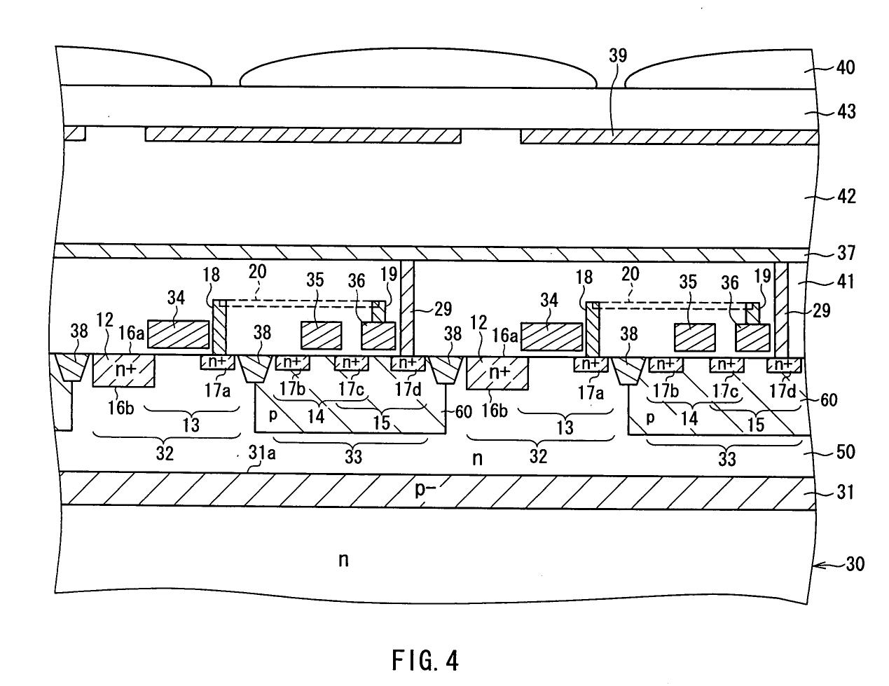

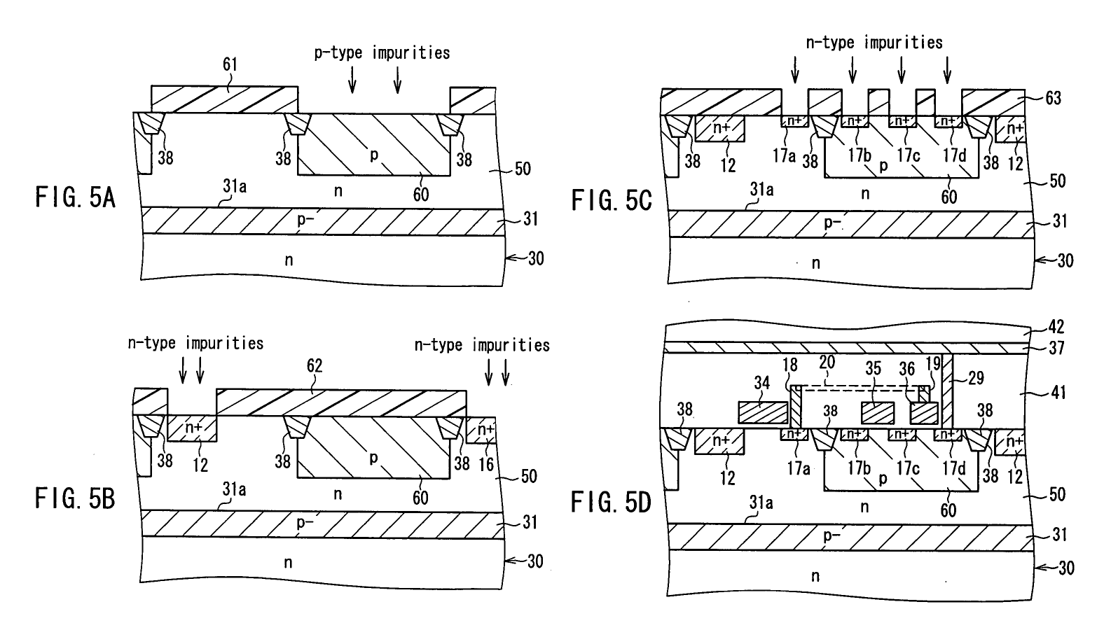

Now, a solid-state imaging device according to Embodiment 2 of the present invention will be described, with reference to FIGS. 4 and 5. The solid-state imaging device according to Embodiment 2 also is a MOS imaging device and has a circuit configuration similar to the conventional MOS imaging device shown in FIG. 12.

First, the cross-sectional structure of the solid-state imaging device according to Embodiment 2 will be described referring to FIG. 4. FIG. 4 is a sectional view showing the structure of the solid-state imaging device according to Embodiment 2 of the present invention. In FIG. 4, portions assigned the reference numerals indicated in FIG. 1 are similar to the portions shown in FIG. 1.

As shown in FIG. 4, in Embodiment 2, second p-wells 60 whose surface side interface coincides with the substrate surface are formed above the p-well 31 in the semiconductor substrate 30. The second p-wells 60 overlap only the signal detection portions 33 when viewed in the thickness direction of the semiconductor substrate 30, and the signal detection portions 33 are formed in a region where the second p-wells 60 are formed.

Furthermore, the impurity concentration of the second p-well 60 is set higher than that of the p-well 31. In Embodiment 2, it is preferable that the impurity concentration of the p-well 31 is set to, for example, 1×10¹⁴ ions/cm³ to 1×10¹⁷ ions/cm³. It is preferable that the impurity concentration of the second p-well 60 is set to be about an order of magnitude greater than that of the p-well 31, for example, 1×10¹⁵ ions/cm³ to 1×10¹⁸ ions/cm³.

As described above, in Embodiment 2, the second p-wells 60 are formed on the semiconductor substrate 30. Therefore, the characteristics of the reset transistor 14 and the amplifying transistor 15 forming the signal detection portion 33 can be stabilized, thus suppressing the malfunction such as latch up in the reset transistor 14 and the amplifying transistor 15. Consequently, according to Embodiment 2, it is possible to stabilize the performance of the signal detection portion 33 compared with Embodiment 1, while suppressing the reduction of the saturation number of electrons in the photodiode 12.

Further, the solid-state imaging device in Embodiment 2 is constituted similarly to that in Embodiment 1 except that the second p-wells 60 are formed. In other words, in Embodiment 2, the p-well 31 also is formed in the semiconductor substrate 30 similarly to Embodiment 1. Thus, the solid-state imaging device in Embodiment 2 also can produce the effects described in Embodiment 1.

It should be noted that the second p-well 60 in Embodiment 2 is not limited to the example illustrated by FIG. 4. For example, the second p-well 60 may be formed such that a non-dope region is present between the signal detection portion 33 and the second p-well 60.

Now, the method for manufacturing the solid-state imaging device according to Embodiment 2 shown in FIG. 4 will be described referring to FIG. 5. FIGS. 5A to 5D are sectional views showing a series of major steps in the method for manufacturing the solid-state imaging device shown in FIG. 4.

First, as shown in FIG. 5A, the element isolation regions 38 and the p-well 31 are formed in this order in the semiconductor substrate 30. The element isolation regions 38 and the p-well 31 are formed similarly to the step illustrated in FIG. 3A in Embodiment 1. Incidentally, in Embodiment 2, the semiconductor substrate 30 is set to have a resistivity of at least 10 Q, in particular, 10Ω to 500Ω.

Subsequently, a resist pattern 61 having openings in a formation region of the second p-wells 60 (the formation region of the signal detection portions 33 (see FIG. 3)) is formed on the semiconductor substrate 30. Then, using the resist pattern 61 as a mask, ions of p-type impurities such as boron (B) are implanted. In this way, the second p-wells 60 are formed. Thereafter, the resist pattern 61 is removed.

However, the second p-wells 60 have to be formed in a region shallower than the p-well 31. Therefore, it is preferable that the second p-wells 60 are formed by 2 to 3 repetitions of ion implantation with an acceleration energy of 100 keV to 800 keV and a dose of 1×10¹⁵ ions/cm² to 1×10¹⁷ ions/cm².

Subsequently, as shown in FIG. 5B, the photodiodes 12 are formed in a region that is located above the p-well 31 (near the surface of the semiconductor substrate 30) and is not provided with the second p-well 60. More specifically, a resist pattern 62 is formed, and then using this as a mask, ions of n-type impurities are implanted. Thereafter, the resist pattern 62 is removed. It should be noted that the photodiodes 12 are formed similarly to the step illustrated by FIG. 3B in Embodiment 1.

Then, as shown in FIG. 5C, the semiconductor regions 17a to 17d are formed. Among these semiconductor regions, the semiconductor regions 17b to 17d are formed in a region provided with the second p-well 60. More specifically, a resist pattern 63 having openings in a formation region of the semiconductor regions 17a to 17d first is formed on the substrate surface of the semiconductor substrate 30, and then using this as a mask, ions of n-type impurities are implanted. Thereafter, the resist pattern 63 is removed. It should be noted that the semiconductor regions 17a to 17d are formed similarly to the step illustrated by FIG. 3C in Embodiment 1.

Subsequently, as shown in FIG. 5D, the gate electrodes 34 to 36, the contact plugs 18, 19 and 29, the wiring 20, the interlayer insulating films 41 to 43, the drain voltage input wiring 37, the light-shielding film 39 and the focusing lens 40 are formed, thus obtaining the solid-state imaging device shown in FIG. 4. In FIG. 5D, the interlayer insulating film 43, the light-shielding film 39 and the focusing lens 40 are omitted.

In Embodiment 2, it is preferable that the second p-wells 60 are formed simultaneously with the ion implantation for controlling the threshold of the reset transistor 14 and the amplifying transistor 15. In this case, the formation of the second p-wells 60 and the threshold control can be carried out in a single step. Thus, the steps can be reduced, resulting in a lower manufacturing cost. Also, in Embodiment 2, it is possible to form the gate electrodes 34 to 36 prior to the step illustrated by FIG. 5C and use them as a mask.

### Embodiment 3

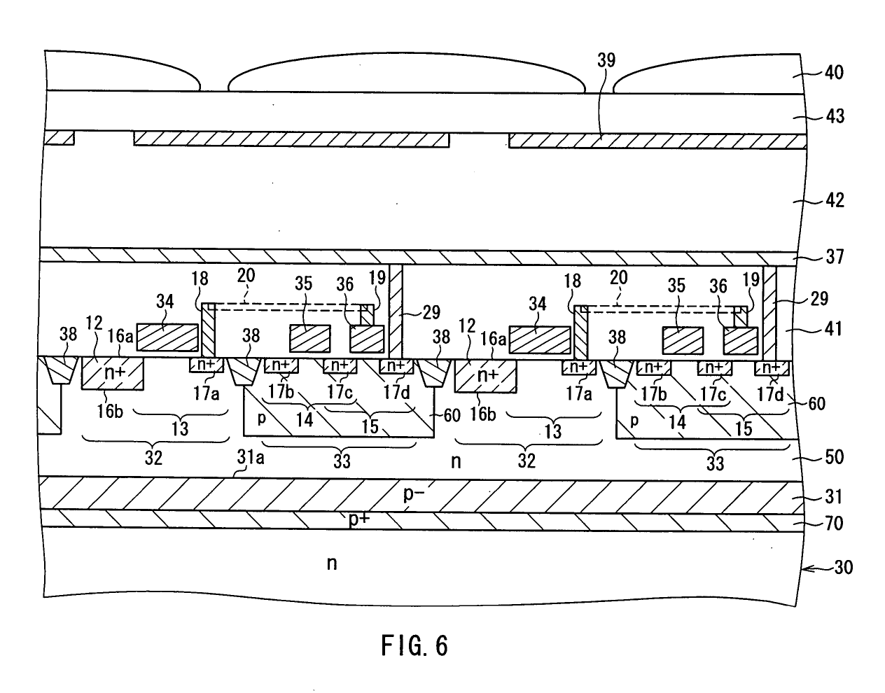

Now, a solid-state imaging device according to Embodiment 3 of the present invention will be described, with reference to FIG. 6. The solid-state imaging device according to Embodiment 3 also is a MOS imaging device and has a circuit configuration similar to the conventional MOS imaging device shown in FIG. 12. FIG. 6 is a sectional view showing the structure of the solid-state imaging device according to Embodiment 3 of the present invention. In FIG. 6, portions assigned the reference numerals indicated in FIGS. 1 and 4 are similar to the portions shown in FIGS. 1 and 4.

As shown in FIG. 6, in Embodiment 3, a p-type buried region 70 having a higher impurity concentration than the p-well 31 is formed below the p-well 31 in the semiconductor substrate 30. The surface side interface of the buried region 70 coincides with the lower side interface of the p-well 31. Further, it is preferable that the impurity concentration of the buried region 70 is set to, for example, 1×10¹⁵ ions/cm³ to 1×10¹⁸ ions/cm³ similarly to the second p-well 60.

Also, the buried region 70 can be formed simultaneously with forming the p-well (not shown) in the peripheral region of the image capturing region (see FIG. 12) before forming the p-well 31. At this time, the ion implantation preferably is carried out under the condition set so that, for example, boron (B) is used as the impurities, the acceleration energy is 300 keV to 1000 keV, preferably about 800 keV, and the dose is 1×10¹² ions/cm² to 1×10¹⁴ ions/cm².

As described above, in Embodiment 3, the buried region 70 is formed below the p-well 31 and has a higher potential in energy than the p-well 31. Thus, according to Embodiment 3, the intrusion of the electrons generated in an area deeper than the p-well 31 into the photoelectric conversion portion 32 can be suppressed further compared with Embodiments 1 and 2. In other words, according to Embodiment 3, the occurrence of blooming and color mixture can be suppressed further compared with Embodiments 1 and 2.

Further, the solid-state imaging device in Embodiment 3 is constituted similarly to that in Embodiment 2 except that the buried region 70 is formed. Thus, the solid-state imaging device in Embodiment 3 also can produce the effects described in Embodiment 2. It should be noted that the solid-state imaging device according to Embodiment 3 is appropriate as long as it includes the buried region 70. Although not shown in the figure, it also may be possible to provide no second p-well 60 as in Embodiment 1.

### Embodiment 4

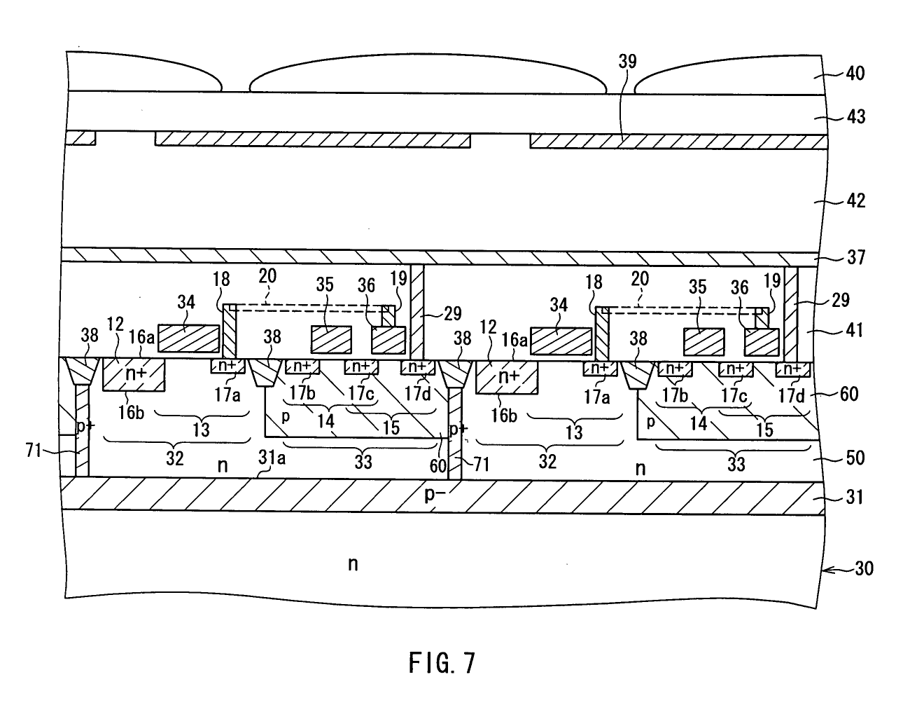

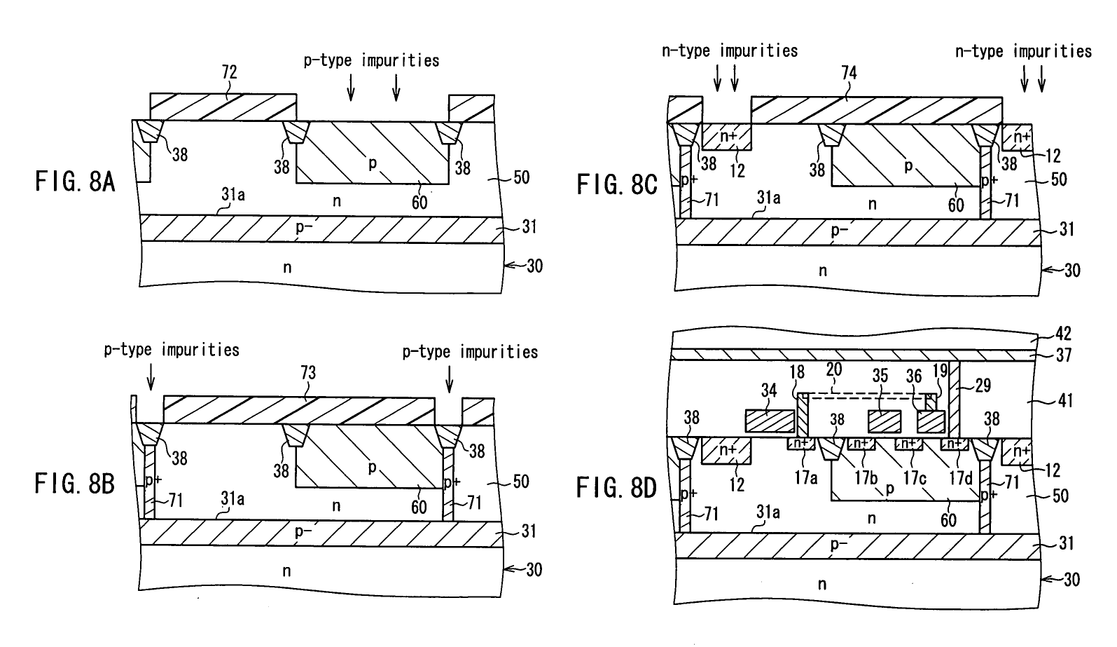

Now, a solid-state imaging device according to Embodiment 4 of the present invention will be described, with reference to FIGS. 7 and 8. The solid-state imaging device according to Embodiment 4 also is a MOS imaging device and has a circuit configuration similar to the conventional MOS imaging device shown in FIG. 12.

First, the cross-sectional structure of the solid-state imaging device according to Embodiment 4 will be described referring to FIG. 7. FIG. 7 is a sectional view showing the structure of the solid-state imaging device according to Embodiment 4 of the present invention. In FIG. 7, portions assigned the reference numerals indicated in FIGS. 1 and 4 are similar to the portions shown in FIGS. 1 and 4.

As shown in FIG. 7, in Embodiment 4, a p-type buried region 71 is formed below the element isolation region 38 located at the border between adjacent pixels among the element isolation regions 38 formed on the semiconductor substrate 30, so as to separate the pixels. In addition, the buried region 71 extends from the lower side interface of the element isolation region 38 to the p-well 31.

Furthermore, the impurity concentration of the buried region 71 is set higher than that of the p-well 31. In Embodiment 4, it is preferable that the impurity concentration of the p-well 31 is set to, for example, 1×10¹⁴ ions/cm³ to 1×10¹⁷ ions/cm³. It is preferable that the impurity concentration of the buried region 71 is set to be about an order of magnitude greater than that of the p-well 31, for example, 1×10¹⁵ ions/cm³ to 1×10¹⁸ ions/cm³.

As described above, in Embodiment 4, the buried region 71 is formed. Thus, according to Embodiment 4, the intrusion of the electrons generated in an area deeper than the p-well 31 into the photoelectric conversion portion 32 can be suppressed further compared with Embodiments 1 and 2. In other words, according to Embodiment 4, the occurrence of blooming and color mixture can be suppressed further compared with Embodiments 1 and 2.

Further, the solid-state imaging device in Embodiment 4 is constituted similarly to that in Embodiment 2 except that the buried regions 71 are formed. Thus, the solid-state imaging device in Embodiment 4 also can produce the effects described in Embodiment 2.

Although the depth of the buried region 71 is not particularly limited, it preferably is set to be deeper than the lower side interface of the second p-well 60 considering the effectiveness in suppressing the electron intrusion into the pixels.

Now, the method for manufacturing the solid-state imaging device according to Embodiment 4 shown in FIG. 7 will be described referring to FIG. 8. FIGS. 8A to 8D are sectional views showing a series of major steps in the method for manufacturing the solid-state imaging device shown in FIG. 7.

First, as shown in FIG. 8A, after the element isolation regions 38 and the p-well 31 are formed in this order, a resist pattern 72 having openings in a formation region of the second p-wells 60 is formed on the semiconductor substrate 30, and then, using this as a mask, ions of p-type impurities such as boron (B) are implanted. In this way, the second p-wells 60 are formed. Thereafter, the resist pattern 72 is removed. This step is carried out similarly to the step illustrated by FIG. 5A in Embodiment 2.

Subsequently, as shown in FIG. 8B, a resist pattern 73 having openings in a formation region of the buried regions 71 (i.e., a region above the element isolation region 38 at the border between the pixels) is formed. Then, using the resist pattern 73 as a mask, ions of p-type impurities such as boron (B) are implanted, thus forming the buried regions 71.

At this time, the ion implantation preferably is carried out 2 to 4 times under the condition set so that, for example, the acceleration energy is 100 keV to 1000 keV and the dose is 1×10¹⁵ ions/cm² to 1×10¹⁸ ions/cm². This makes it possible to distribute the impurity ions substantially uniformly between the p-well 31 and the element isolation region 38.

Subsequently, as shown in FIG. 8C, the photodiodes 12 are formed in a region that is located above the p-well 31 (near the surface of the semiconductor substrate 30) and is not provided with the second p-well 60. More specifically, a resist pattern 74 is formed, and then using this as a mask, ions of n-type impurities are implanted. Thereafter, the resist pattern 74 is removed. It should be noted that the photodiodes 12 are formed similarly to the step illustrated by FIG. 3B in Embodiment 1.

Then, as shown in FIG. 8D, the semiconductor regions 17a to 17d serving as the source or the drain of the transistors are formed. The semiconductor regions 17a to 17d are formed similarly to the step illustrated by FIG. 3C in Embodiment 1.

Furthermore, the gate electrodes 34 to 36, the contact plugs 18, 19 and 29, the wiring 20, the interlayer insulating films 41 to 43, the drain voltage input wiring 37, the light-shielding film 39 and the focusing lens 40 are formed, thus obtaining the solid-state imaging device shown in FIG. 7. In FIG. 8D, the interlayer insulating film 43, the light-shielding film 39 and the focusing lens 40 are omitted.

It should be noted that the solid-state imaging device according to Embodiment 4 is suitable as long as it includes the buried region 71. Although not shown in the figure, it also may be possible to provide no second p-well 60 as in Embodiment 1.

### Embodiment 5

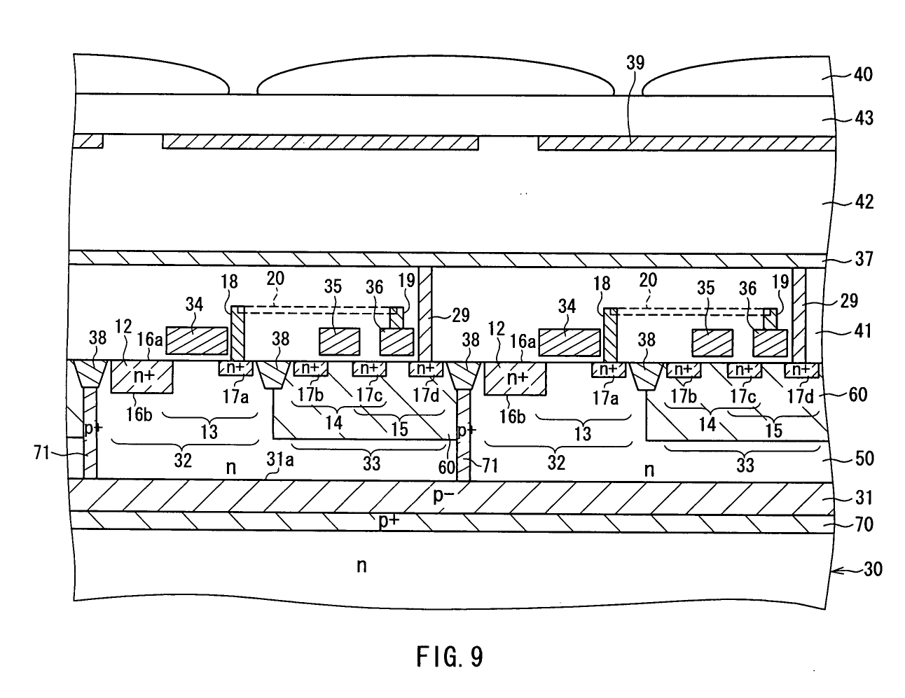

Now, a solid-state imaging device according to Embodiment 5 of the present invention will be described, with reference to FIG. 9. The solid-state imaging device according to Embodiment 5 also is a MOS imaging device and has a circuit configuration similar to the conventional MOS imaging device shown in FIG. 12. FIG. 9 is a sectional view showing the structure of the solid-state imaging device according to Embodiment 5 of the present invention. In FIG. 9, portions assigned the reference numerals indicated in FIGS. 1, 4, 6 and 7 are similar to the portions shown in FIGS. 1, 4, 6 and 7.

As shown in FIG. 9, the solid-state imaging device according to Embodiment 5 includes the characteristics of the solid-state imaging device according to Embodiment 3 shown in FIG. 6 and that according to Embodiment 4 shown in FIG. 7. In other words, in Embodiment 5, the p-type buried region 70 having a higher impurity concentration than the p-well 31 is formed below the p-well 31 in the semiconductor substrate 30. Also, the p-type buried region 71 is formed below the element isolation region 38 located at the border between adjacent pixels among the element isolation regions 38 formed on the semiconductor substrate 30, so as to separate the pixels.

Consequently, in the solid-state imaging device in Embodiment 5, each pixel is surrounded by the buried region 70 and the buried regions 71. Therefore, in accordance with Embodiment 5, the occurrence of blooming and color mixture can be suppressed further compared with Embodiments 3 and 4.

### Embodiment 6

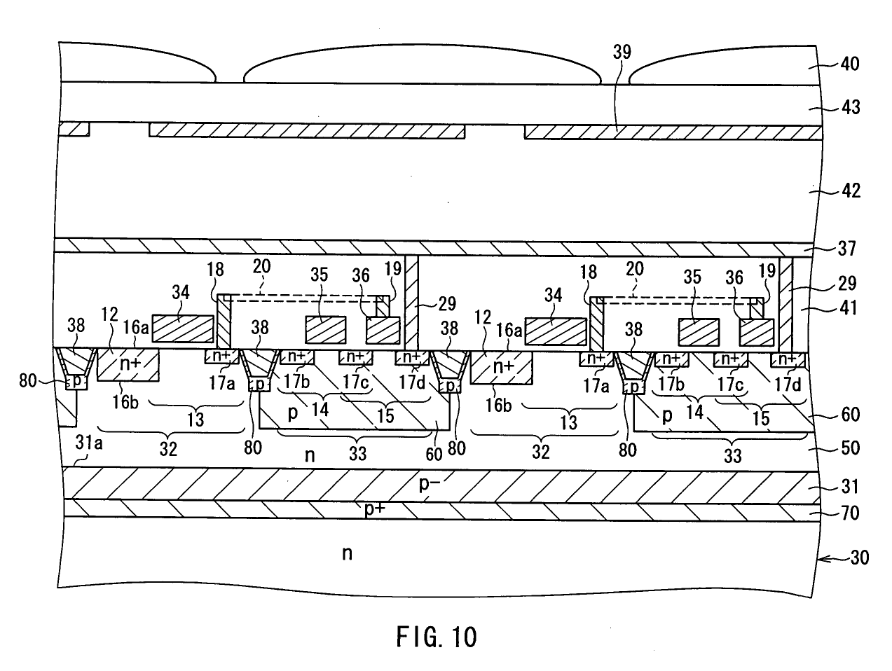

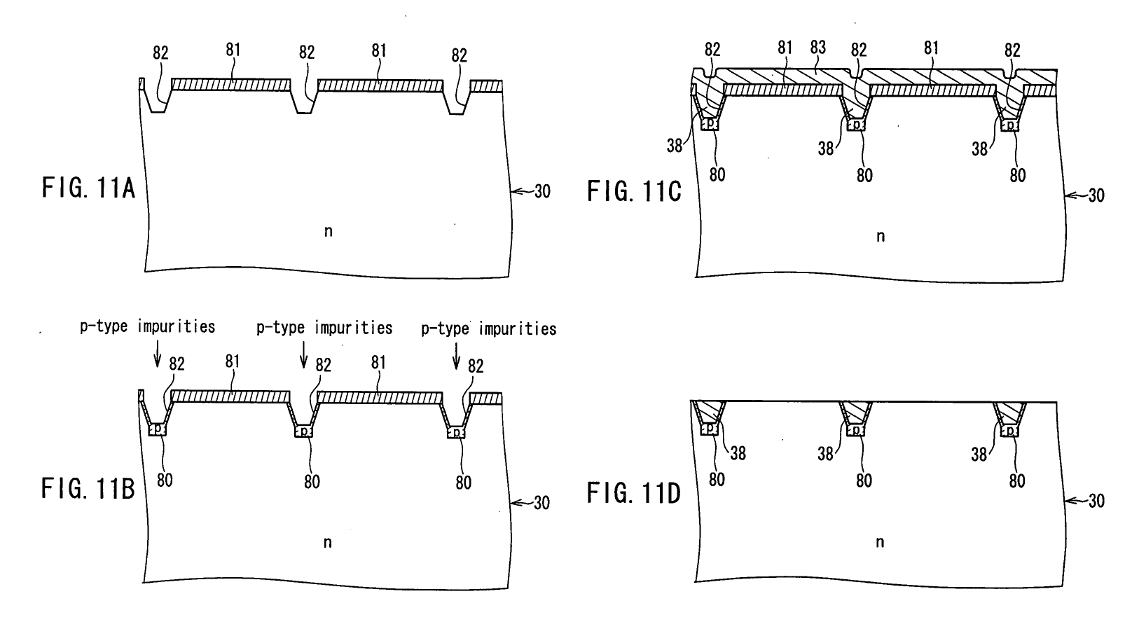

Now, a solid-state imaging device according to Embodiment 6 of the present invention will be described, with reference to FIGS. 10 and 11. The solid-state imaging device according to Embodiment 6 also is a MOS imaging device and has a circuit configuration similar to the conventional MOS imaging device shown in FIG. 12.

First, the cross-sectional structure of the solid-state imaging device according to Embodiment 6 will be described referring to FIG. 10. FIG. 10 is a sectional view showing the structure of the solid-state imaging device according to Embodiment 6 of the present invention. In FIG. 10, portions assigned the reference numerals indicated in FIGS. 1, 4 and 6 are similar to the portions shown in FIGS. 1, 4 and 6.

As shown in FIG. 10, in Embodiment 6, a p-type semiconductor region 80 is formed in a region including an interface between the element isolation region 38 and other regions. The semiconductor region 80 extends at the interface between the element isolation region 38 and the other regions and the vicinity thereof. In Embodiment 6, it is preferable that the semiconductor region 80 is formed in the range of about 1 nm to 100 nm, in particular, about 5 nm to 30 nm in the depth direction of the semiconductor substrate 30 from the interface of the element isolation region 38 and the other regions.

Furthermore, the impurity concentration of the semiconductor region 80 is set higher than that of the second p-well 60. In Embodiment 6, it is preferable that the impurity concentration of the second p-well 60 is set to, for example, 1×10¹⁵ ions/cm³ to 1×10¹⁸ ions/cm³. It is preferable that the impurity concentration of the semiconductor region 80 is set to, for example, 1×10¹⁶ ions/cm³ to 1×10¹⁹ ions/cm³.

As described above, in Embodiment 6, the semiconductor regions 80 are formed. Thus, according to Embodiment 6, the electron leakage occurring between pixels can be suppressed compared with Embodiment 2. In accordance with Embodiment 6, the occurrence of blooming and color mixture caused by the electron leakage occurring between pixels can be suppressed compared with Embodiment 2.

Further, the solid-state imaging device in Embodiment 6 is constituted similarly to that in Embodiment 3 except that the semiconductor regions 80 are formed. Thus, the solid-state imaging device in Embodiment 6 also can produce the effects described in Embodiment 3.

Now, the method for manufacturing the solid-state imaging device according to Embodiment 6 shown in FIG. 10 will be described referring to FIG. 11. FIGS. 11A to 11D are sectional views showing a series of major steps in the method for manufacturing the solid-state imaging device shown in FIG. 10.

First, as shown in FIG. 11A, a substrate protection film 81 is formed on the semiconductor 30, and then trenches 82 are formed in the formation region of the element isolation regions 38. In Embodiment 6, the substrate protection film 81 is a laminated film obtained by forming a silicon oxide film and a silicon nitride film sequentially.

Next, as shown in FIG. 11B, using the remaining substrate protection film as a mask, ions of p-type impurities such as boron are implanted. In this way, the semiconductor regions 80 are formed. At this time, the ion implantation preferably is carried out 1 to 3 times under the condition set so that, for example, the acceleration energy (acceleration voltage) is 5 keV to 100 keV and the dose is 1×10¹⁶ ions/cm² to 1×10¹⁹ ions/cm².

Subsequently, as shown in FIG. 11C, an insulating film 83 of a silicon oxide film or the like is formed so as to fill inside the trenches 82. Then, as shown in FIG. 11D, the surface of the semiconductor substrate 30 is flattened by polishing so that the insulating film 83 remains only inside the trenches 82. In this way, the element isolation regions 38 whose interface is provided with the semiconductor region 80 are formed.

Next, although not shown in FIG. 11, the buried region 70, the p-well 31 and the second p-wells 60, the photodiodes 12 and the semiconductor regions 17a to 17d are formed similarly to Embodiments 1 to 5 (see FIGS. 5A to 5C). Furthermore, the gate electrodes 34 to 36, the contact plugs 18, 19 and 29, the wiring 20, the interlayer insulating films 41 to 43, the drain voltage input wiring 37, the light-shielding film 39 and the focusing lens 40 are formed, thus obtaining the solid-state imaging device shown in FIG. 10.

In Embodiment 6, the semiconductor region 80 is formed at the interface between the element isolation region 38 and the other regions in a self-aligned manner. Thus, according to Embodiment 6, the pixel size (the distance between the element isolation regions 38) can be reduced more easily compared with Embodiment 5. This is because, since the element isolation region 38 and the buried region 71 are formed in separate steps in Embodiment 5, the element isolation region 38 has to be formed larger than that in Embodiment 6 considering a mask displacement.

It should be noted that the solid-state imaging device according to Embodiment 6 may include no second p-well 60 or no buried region 70 as in Embodiment 1.

In FIGS. 1, 3 to 10 referred to in Embodiments 1 to 6 described above, the hatching is omitted for the interlayer insulating films 41 to 43. Further, the hatching also is omitted for the region in the semiconductor substrate 30 in which impurities are not introduced by ion implantation. In addition, in each of the sectional views, only the lines appearing in the cross-section are shown.

In accordance with the solid-state imaging device of the present invention, it is possible to solve both of the problems that are inconsistent with each other, i.e., the occurrence of blooming and color mixture and the reduction of the maximum number of electrons in the photodiode and the sensitivity. Therefore, the solid-state imaging device according to the present invention is useful for applications to a video camera, a digital still camera and the like.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A solid-state imaging device comprising:
an n-type semiconductor substrate comprising
a photoelectric conversion portion for converting incident light into a signal charge, and
a signal detection portion for detecting the signal charge;
wherein the photoelectric conversion portion comprises a photodiode formed in the semiconductor substrate,
the semiconductor substrate comprises a p-well that overlaps the photoelectric conversion portion and the signal detection portion when viewed in a thickness direction of the semiconductor substrate, and
the p-well is formed so that a surface side interface is located below a surface side interface of the photodiode.

2. The solid-state imaging device according to claim 1, wherein the p-well is formed so that the surface side interface of the p-well is located below a lower side interface of the photodiode and an impurity profile of the p-well does not overlap that of the photodiode, and
a region in which no impurity is introduced by a step other than a forming step of the semiconductor substrate is present between the photodiode and the p-well.

3. The solid-state imaging device according to claim 2, wherein an impurity concentration of n-type impurities is 1×10¹² ions/cm³ to 1×10¹⁶ ions/cm³ and that of p-type impurities is 1×10¹² ions/cm³ to 1×10¹⁶ ions/cm³ in the region in which no impurity is introduced by the step other than the forming step of the semiconductor substrate.

4. The solid-state imaging device according to claim 1, wherein the p-well is formed so that the surface side interface of the p-well is located between a surface side interface of the photodiode and a lower side interface thereof.

5. The solid-state imaging device according to claim 1, wherein the semiconductor substrate comprises a second p-well that is located above the p-well and has a higher impurity concentration than the p-well, and
the signal detection portion is formed in a region where the second p-well is formed.

6. The solid-state imaging device according to claim 1, wherein the semiconductor substrate comprises a p-type buried region that is located below the p-well and has a higher impurity concentration than the p-well.

7. The solid-state imaging device according to claim 1, wherein a plurality of the photoelectric conversion portions and a plurality of the signal detection portions are formed in the semiconductor substrate,
the plurality of the photoelectric conversion portions and the plurality of the signal detection portions function as a plurality of pixels,
the plurality of pixels are arranged in a matrix, and
an element isolation region is formed between the pixels adjacent to each other in the semiconductor substrate.

8. The solid-state imaging device according to claim 7, wherein the semiconductor substrate comprises a p-type second buried region that is formed below the element isolation region so as to have a higher impurity concentration than the p-well and separate the pixels.

9. The solid-state imaging device according to claim 7, wherein the semiconductor substrate comprises a second p-well that is located above the p-well and has a higher impurity concentration than the p-well, and a p-type semiconductor region having a higher impurity concentration than the second p-well in a region including an interface between the element isolation region and other regions, and
the signal detection portion is formed in a region where the second p-well is formed.
